(19) United States
(12) Patent Application Publication
(10) Pub. No.: US 2011/0162703 A1
(43) Pub. Date: Jul. 7, 2011

(54) ADVANCED HIGH EFFICIENTCY CRYSTALLINE SOLAR CELL FABRICATION METHOD

(75) Inventors: Babak Adibi, Los Altos, CA (US); Edward S. Murrer, Aptos, CA (US); Henry Hieslmair, San Francisco, CA (US)

(73) Assignee: SOLAR IMPLANT TECHNOLOGIES, INC., Mountain View, CA (US)

(21) Appl. No.: 12/728,105

(22) Filed: Mar. 19, 2010

Related U.S. Application Data
(60) Provisional application No. 61/210,545, filed on Mar. 20, 2009.

(51) Int. Cl. H01L 31/0216; H01L 31/0232; H01L 31/0224; H01L 31/18

(52) U.S. Cl. 136/256; 438/72; 257/E31.127

(57) ABSTRACT

A method of fabricating a solar cell comprising: providing a semiconducting wafer having a front surface, a back surface, and a background doped region; performing a set of ion implantations of dopant into the semiconducting wafer to form a back alternatingly-doped region extending from the back surface of the semiconducting wafer to a location between the back surface and the front surface, wherein the back doped region comprises laterally alternating first back doped regions and second back doped regions, and wherein the first back doped regions comprise a different charge type than the second back doped regions and the background doped region; and disposing a back metal contact layer onto the back surface of the semiconducting wafer, wherein the back metal contact layer is aligned over the first and second back doped regions and is configured to conduct electrical charge from the first and second back doped regions.

### CROSS-REFERENCE TO RELATED APPLICATIONS

This application claims priority to co-pending U.S. Provisional Application Ser. No. 61/210,545, filed Mar. 20, 2009, entitled “ADVANCED HIGH EFFICIENCY CRYSTALLINE SOLAR CELL FABRICATION METHOD,” which is hereby incorporated by reference as if set forth herein.

### FIELD OF THE INVENTION

The present invention relates generally to the field of solar cells. More particularly, the present invention relates to solar cell devices and methods of their formation.

### BACKGROUND OF THE INVENTION

The present invention addresses advanced methods for the fabrication of high efficiency crystalline solar cells that are enabled by the use of unique implant and annealing methodology, in contrast to the older methods of diffusion doping and metallization by screen printing.

Use of diffusion of dopant from the surface in to the substrate is plagued by problems. One of the main issues is the snow plowing of the dopants near the surface as the dopants are driven in to the bulk of the material, which can vary the resistivity in different regions of the substrate and thus lead to varying light absorption and electron hole formation performance that can result in excess surface recombination (i.e., a “dead layer”). In particular, one problem encountered is the lack of utilization of the blue light as the result of formation of such “dead layer.”

Additionally, lateral positioning of the dopants across the substrate is becoming difficult as the line widths and wafer thicknesses are getting smaller. The solar cell industry is expected to require dopant lateral placements, for selective emitter and interdigitated back contact applications for example, to be from 200 microns down to less than 50 microns, which is extremely difficult for the present methodology of diffusion and screen printing. Moreover, as the wafers get thinner from 150-200 microns of today to 50 microns and below, vertical and batch diffusion and contact screen printing becomes extremely difficult or even impossible.

### SUMMARY OF THE INVENTION

The present invention provides alternative fabrications methods, that in part or as a whole can provide higher efficiency solar cells. It utilizes directed implant techniques to form various emitter regions and doped back surface field (BSF), both homogeneous and selective emitter regions in an interdigitated back surface contact (IBC) cell, as well as formation of mesotaxial layers (seed implants). The BSF can comprise homogeneous or selective emitter regions for interdigitated formation of alternative doping regions in order to eliminate front surface shading. The present invention also addresses the formation of contacts to emitters and BSF regions through selective metallization, either by implantation, laser, plating, or ink jet printing. The essence of the first discovery is the use of a very cost effective self-aligned selective implant method that simplifies the cell processing.

Some of the advantages of this methodology are to minimize the resistance of contact, busbar, fingers, contact resistance of metal-silicon interface, resistance of backside metallization, and achieving the desired resistivity under the grid contact and in between the fingers. Moreover, the advantageous formation of selective emitter and BSF and its ability to improve performance is made possible by the present invention. It can be applied to as-grown single or mono-crystalline, poly or multi-crystalline silicon, as well as very thin film deposited silicon, or other materials used for solar cell formation and other applications. It can also be extended to atomic species placement for any other material used in fabrication of junctions or contacts.

Application specific ion implantation and annealing systems and methods are adopted to provide the appropriate placement of dopant both within the bulk of the material and laterally positioned across the substrate. Accordingly, the present invention can employ the fabrication methods and systems discussed in U.S. patent application Ser. No. 12/483,017, entitled “FORMATION OF SOLAR CELL-SELECTIVE EMITTER USING IMPLANT AND ANNEAL METHOD,” filed Jun. 11, 2009, and in U.S. Provisional Application No. 61/131,698, entitled “FORMATION OF SOLAR CELL-SELECTIVE EMITTER USING IMPLANT AND ANNEAL METHOD,” filed Jun. 11, 2008, which are both hereby incorporated by reference as if set forth herein. These patent applications disclose the ability to independently control any species and dopant positioning and provide the necessary surface concentration, junction depth, and shape of the dopant profile. In these patent applications, an Application Specific Implanter is described that can provide a plurality of dopants, selectively and otherwise. The present invention can also include the impact of surface conditionings and variability of texturing discussed in U.S. patent application Ser. No. 12/482,947, entitled “APPLICATION SPECIFIC IMPLANT SYSTEM AND METHOD FOR USE IN SOLAR CELL FABRICATIONS,” filed Jun. 11, 2009, and in U.S. Provisional Application No. 61/131,688, entitled “APPLICATIONS SPECIFIC IMPLANT SYSTEM AND METHOD FOR USE IN SOLAR CELL FABRICATIONS,” filed Jun. 11, 2008, which are both hereby incorporated by reference as if set forth herein. In present invention, the use of accurate and highly placed dopant and tailoring of dopant atomic profile methods are employed in order to provide heavily doped selective emitter regions (e.g., 10-40 Ohms/square) placed under the grid line, as well as methods to achieve lightly doped homogeneous emitter regions (e.g., 80-160 Ohms/square) in between grid fingers. Additionally, through the use of tailored parameters, the atomic dopant profile is simultaneously matched to provide the electrical junctions at the appropriate depth against the substrate doping levels and provide the resistivity required for the formation of the contacts on the surface. In some embodiments, use of retrograde doping and flat atomic profile (box junctions) are also employed. Furthermore, such capability will allow for independent doping of surfaces, such as emitter and BSF. Again, selective dopant capability can allow for an interdigitated doping profile on the back surface that eliminates the front surface shadowing. It is proposed that such capability alone can provide efficiency gains in advance of 1 to 2 absolute percentage points.

Furthermore, since the positioning of the dopant placement through ion implantation is highly controlled, side and back side doping can be controlled or minimized to avoid subsequent removal of such dopant. At present, etch or laser edging is used to remove the deleterious effect of all encompassing dopant diffusion methods that can dope all sides simultaneously. Careful management of implant start and end, as well as dopant placement are discussed with respect to this subject in U.S. patent application Ser. No. 12/482,980, entitled “SOLAR CELL FABRICATION USING IMPLANTATION,” filed Jun. 11, 2009, and in U.S. Provisional Application No. 61/131,687, entitled “SOLAR CELL FABRICATION USING IMPLANTATION,” filed Jun. 11, 2008, which are both hereby incorporated by reference as if set forth herein.

The use of implanted dopants and activation of such is discussed in the previously referenced patent applications, where by controlled use of annealing time and temperature provides a further enhancement of atomic profile within the substrate.

Additionally, the textured surface required for a solar cell may require specialized implantation techniques. Such implantation techniques are the subject of U.S. patent application Ser. No. 12/482,685, entitled “SOLAR CELL FABRICATION WITH FACETING AND ION IMPLANTATION,” filed Jun. 11, 2009, and in U.S. Provisional Application No. 61/133,028, entitled “SOLAR CELL FABRICATION WITH FACETING AND ION IMPLANTATION,” filed Jun. 24, 2008, which are both hereby incorporated by reference as if set forth herein. The present invention can employ such techniques, whereby the directed implanted dopants can be best used to enhance a facetted surface.

Ion implantation can be used by the present invention to implant almost any species from the periodic table into a semiconducting wafer. This capability can be used for the seeding implant, which is the subject of the previously referenced patent applications, whereby the appropriate element (metals or combination of different species) can be implanted at or near the surface of the semiconducting wafer, or in any film covering the surface, in order to provide an initiation point for the subsequent growth or deposition of the same element (metal or otherwise) or other elements to form the necessary components of the solar cell (formation of contact, silicidation, etc.). This method can be used to affect the work function of the metal semiconductor interface or tailor the band gap to enhance the performance of the solar cell, such as through improving the contacts. For this purpose, implantation of metals at medium to low levels can be used to seed and prepare the subsequent process. This implantation will minimize the need to adopt the use of high temperature firing methods employed today, resulting in a much lower temperature time regimes, and thereby avoiding the deleterious effects of multi-crystalline cells at high thermal budgets.

The selectivity of doping can be addressed in many different ways, as described in the previously referenced applications, where a shadow mask is adopted to provide the selectivity required, as discussed in U.S. Provisional Application No. 61/302,861, entitled “AN ADJUSTABLE SHADOW MASK ASSEMBLY FOR USE IN SOLAR CELL FABRICATIONS,” filed Feb. 9, 2010, which is hereby incorporated by reference as if set forth herein. Another simple and cost effective method is the use of in-contact mask exposure and resists patterning prevalent in other industries. This method provides the exact selectivity required to dope the regions below the contact gridlines. The issue of subsequent alignment of the metal gridlines is a critical one and needs to be addressed with accuracies in sub-10's of microns. Such patterning eliminates the needs for such alignment. Furthermore, it provides a vehicle to adopt the inexpensive and cost efficient electro- and electro-less plating techniques, which is discussed below. Additionally, use of novel techniques, such as selective printing methods is also demonstrated here. It is expected that such fabrication methods will provide additional efficiency gains.

In one aspect of the present invention, a solar cell comprises a semiconducting wafer having a front surface, a back surface, and a background doped region between the front surface and the back surface. A front alternatingly-doped region extends from the front surface of the semiconducting wafer to a location between the front surface and the back surface. The front doped region comprises laterally alternating first front doped regions and second front doped regions. The second front doped regions have a lower sheet resistance than the first front doped regions. A p-n junction is formed between the first front doped regions and the background doped region. A plurality of front metal contacts are aligned over the second front doped regions. The front metal contacts are configured to conduct electrical charge from the second front doped regions. A back alternatingly-doped region extends from the back surface of the semiconducting wafer to a location between the back surface and the front surface. The back doped region comprises laterally alternating first back doped regions and second back doped regions. The second back doped regions have a lower sheet resistance than the first back doped regions. A back metal contact layer is disposed on the back surface of the semiconducting wafer. The back metal contact layer covers the first back doped regions and the second back doped regions and is configured to conduct electrical charge from the second back doped regions.

In some embodiments, the semiconducting wafer is a silicon substrate. In some embodiments, the first front doped regions and the first back doped regions have a sheet resistance between approximately 80 Ohms/square and approximately 160 Ohms/square. In some embodiments, the second front doped regions and the second back doped regions have a sheet resistance between approximately 10 Ohms/square and approximately 40 Ohms/square. In some embodiments, the background doped region has a sheet resistance between approximately 0.5 Ohms/square and approximately 1.5 Ohms/square.

In some embodiments, the solar cell further comprises an anti-reflective coating layer disposed on the front surface of the semiconducting wafer over the first front doped regions.

In some embodiments, the solar cell further comprises a metallic seed layer disposed over the second front doped regions and under the front metal contacts. In some embodiments, the metallic seed layer comprises mesotaxy implants. In some embodiments, the metallic seed layer comprises a silicide.

In some embodiments, the second front doped regions are laterally spaced apart from one another a distance in the range of approximately 1 mm to approximately 3 mm.

In some embodiments, the background doped region is p-type doped, and the first front doped regions and the second front doped regions are n-type doped. In some embodiments, the second back doped regions are doped with the same charge-type dopant as the background doped region. In some embodiments, the first back doped regions are doped with the same charge-type dopant as the second back doped regions and the background doped region. In some embodiments, the second back doped regions and the background doped region are p-type doped. In some embodiments, the second back doped regions are doped with boron.

In another aspect of the present invention, a method of fabricating a solar cell comprises providing a semiconducting wafer having a front surface, a back surface, and a background doped region between the front surface and the back surface. A first set of ion implantations of dopant into the semiconducting wafer is performed to form a front alternatingly-doped region extending from the front surface of the semiconducting wafer to a location between the front surface and the back surface. The front doped region comprises laterally alternating first front doped regions and second front doped regions. The second front doped regions have a lower sheet resistance than the first front doped regions. A p-n junction is formed between the first front doped regions and the background doped region. A plurality of front metal contacts are disposed on the semiconducting wafer. The front metal contacts are aligned over the second front doped regions and are configured to conduct electrical charge from the second front doped regions. A second set of ion implantations of dopant into the semiconducting wafer is performed to form a back alternatingly-doped region extending from the back surface of the semiconducting wafer to a location between the back surface and the front surface. The back doped region comprises laterally alternating first back doped regions and second back doped regions. The second back doped regions have a lower sheet resistance than the first back doped regions. A back metal contact layer is disposed onto the back surface of the semiconducting wafer. The back metal contact layer covers the first back doped regions and the second back doped regions and is configured to conduct electrical charge from the second back doped regions.

In some embodiments, performing the first set of ion implantations comprises implanting the second front doped regions using a resist layer that comprises resist openings that are aligned with the locations on the semiconducting wafer where the second front doped regions are to be implanted. In some embodiments, the resist openings are formed using a contact mask placed in contact with the resist layer, the contact mask comprising mask openings that are aligned with the locations in the resist layer where the resist openings are to be formed.

In some embodiments, performing the second set of ion implantations comprises implanting the second back doped regions using a shadow mask that comprises mask openings that are aligned with the locations on the semiconducting wafer where the second back doped regions are to be implanted, and the shadow mask is disposed a predetermined distance away from the back surface of the semiconducting wafer during a portion of the second set of ion implantations.

In some embodiments, the semiconducting wafer is a silicon substrate. In some embodiments, the first front doped regions and the first back doped regions have a sheet resistance between approximately 80 Ohms/square and approximately 160 Ohms/square. In some embodiments, the second front doped regions and the second back doped regions have a sheet resistance between approximately 10 Ohms/square and approximately 40 Ohms/square. In some embodiments, the background doped region has a sheet resistance between approximately 0.5 Ohms/square and approximately 1.5 Ohms/square.

In some embodiments, the method further comprises the step of disposing an anti-reflective coating layer on the front surface of the semiconducting wafer over the first front doped regions.

In some embodiments, the method further comprises the step of disposing a metallic seed layer over the second front doped regions, wherein the front metal contacts are disposed over the metallic seed layer. In some embodiments, the metallic seed layer comprises mesotaxy implants. In some embodiments, the metallic seed layer comprises a silicide.

In some embodiments, the second front doped regions are laterally spaced apart from one another a distance in the range of approximately 1 mm to approximately 3 mm.

In some embodiments, the background doped region is p-type doped, and the first front doped regions and the second front doped regions are n-type doped. In some embodiments, the second back doped regions are doped with the same charge-type dopant as the background doped region. In some embodiments, the first back doped regions are doped with the same charge-type dopant as the second back doped regions and the background doped region. In some embodiments, the second back doped regions and the background doped region are p-type doped. In some embodiments, the second back doped regions are doped with boron.

In yet another aspect of the present invention, a solar cell comprises a semiconducting wafer having a front surface, a back surface, and a background doped region between the front surface and the back surface. A back alternatingly-doped region extends from the back surface of the semiconducting wafer to a location between the back surface and the front surface. The back doped region comprises laterally alternating first back doped regions and second back doped regions. The first back doped regions comprise a different charge type than the second back doped regions and the background doped region. A back metal contact layer is disposed on the back surface of the semiconducting wafer. The back metal contact layer is aligned over the first and second back doped regions and is configured to conduct electrical charge from the first and second back doped regions.

In some embodiments, the front surface of the semiconducting wafer is characterized by an absence of any metal contacts, thereby eliminating any front surface shadowing by metal contacts.

In some embodiments, the background doped region is n-type doped, the first back doped regions are p-type doped, and the second back doped regions are n-type doped. In some embodiments, the first back doped regions are doped with a dopant chosen from the group consisting of: boron, aluminum, and gallium. In some embodiments, the second back doped regions are doped with a dopant chosen from the group consisting of: phosphorous, arsenic, and antimony. In some embodiments, the semiconducting wafer is a silicon substrate. In some embodiments, the solar cell further comprises a front doped region extending from the front surface of the semiconducting wafer to a location between the front surface and the back surface, wherein the front doped region does not extend to or past the location of the back alternatingly-doped region. In some embodiments, the front doped region is p-type doped.

In some embodiments, the back metal contact layer comprises metal contact gridlines aligned over the first and second back doped regions. In some embodiments, the solar cell further comprises an anti-reflective coating layer disposed over the back surface of the semiconducting wafer and between the metal contact gridlines. In some embodiments, the anti-reflective coating layer comprises silicon nitride. In some embodiments, the solar cell further comprises an anti-reflective coating layer disposed over the front surface of the semiconducting wafer. In some embodiments, the anti-reflective coating layer comprises silicon nitride. In yet another aspect of the present invention, a method of fabricating a solar cell comprises providing a semiconducting wafer having a front surface, a back surface, and a background doped region between the front surface and the back surface. A set of ion implantations of dopant into the semiconducting wafer is performed to form a back alternatingly-doped region extending from the back surface of the semiconducting wafer to a location between the hack surface and the front surface. The back doped region comprises laterally alternating first back doped regions and second back doped regions. The first back doped regions comprise a different charge type than the second back doped regions and the background doped region. A back metal contact layer is disposed onto the back surface of the semiconducting wafer. The back metal contact layer is aligned over the first and second back doped regions and is configured to conduct electrical charge from the first and second back doped regions.

In some embodiments, the step of performing a set of ion implantations of dopant into the semiconducting wafer to form a back alternatingly-doped region comprises: performing a blanket ion implantation of a first dopant into the semiconducting wafer, wherein the first dopant is implanted across the entire back surface of the semiconducting wafer; and performing a masked ion implantation of a second dopant into the semiconducting wafer using a shadow mask disposed a predetermined distance away from the back surface of the semiconducting wafer, wherein the shadow mask comprises mask openings that are aligned with the locations on the semiconducting wafer where the second back doped regions are to be implanted.

In some embodiments, the step of performing a set of ion implantations of dopant into the semiconducting wafer to form a back alternatingly-doped region comprises: performing a first masked ion implantation of a first dopant into the semiconducting wafer using a shadow mask disposed a predetermined distance away from the back surface of the semiconducting wafer, wherein the shadow mask comprises mask openings that are aligned with the locations on the semiconducting wafer where the first back doped regions are to be implanted; and performing a second masked ion implantation of a second dopant into the semiconducting wafer using a shadow mask disposed a predetermined distance away from the back surface of the semiconducting wafer, wherein the shadow mask comprises mask openings that are aligned with the locations on the semiconducting wafer where the second back doped regions are to be implanted.

In some embodiments, the background doped region is n-type doped, the first back doped regions are p-type doped, and the second back doped regions are n-type doped. In some embodiments, the first back doped regions are doped with a dopant chosen from the group consisting of: boron, aluminum, and gallium. In some embodiments, the second back doped regions are doped with a dopant chosen from the group consisting of: phosphorous, arsenic, and antimony. In some embodiments, the semiconducting wafer is a silicon substrate.

In some embodiments, the method further comprises the step of performing an ion implantation of a dopant into the semiconducting wafer to form a front doped region extending from the front surface of the semiconducting wafer to a location between the front surface and the back surface, wherein the front doped region does not extend to or past the location of the back alternatingly-doped region. In some embodiments, the front doped region is p-type doped.

In some embodiments, the method further comprises the step of depositing an anti-reflective coating layer over the front surface and the back surface of the semiconducting wafer. In some embodiments, the anti-reflective coating layer is deposited using a Plasma-Enhanced Chemical Vapor Deposition (PECVD) process. In some embodiments, the anti-reflective coating layer comprises silicon nitride. In some embodiments, the step of disposing the back metal contact layer onto the back surface of the semiconducting wafer comprises ablating the anti-reflective coating layer to form separated openings in the anti-reflective coating layer over the first and second back doped regions, and depositing metal contacts within the separated openings. In some embodiments, the step of disposing the back metal contact layer onto the back surface of the semiconducting wafer further comprises performing an electroplating process after the metal contacts have been deposited within the separated openings.

### BRIEF DESCRIPTION OF THE DRAWINGS

FIGS. 1-14B illustrate one embodiment of a method of fabricating a solar cell in accordance with the principles of the present invention.

FIG. 15 illustrates a cross-sectional view of one embodiment of an inter-digitated back-doped solar cell in accordance with the principles of the present invention.

FIGS. 16 illustrates a process flow diagram of one embodiment of a method of fabricating a solar cell in accordance with the principles of the present invention.

FIGS. 17-23 illustrate one embodiment of a method of fabricating an inter-digitated back contact solar cell in accordance with the principles of the present invention.

FIG. 24 illustrates a process flow diagram of one embodiment of a method of fabricating an inter-digitated back contact solar cell in accordance with the principles of the present invention.

### DETAILED DESCRIPTION OF THE INVENTION

The following description is presented to enable one of ordinary skill in the art to make and use the invention and is provided in the context of a patent application and its requirements. Various modifications to the described embodiments will be readily apparent to those skilled in the art and the generic principles herein may be applied to other embodiments. Thus, the present invention is not intended to be limited to the embodiment shown but is to be accorded the widest scope consistent with the principles and features described herein.

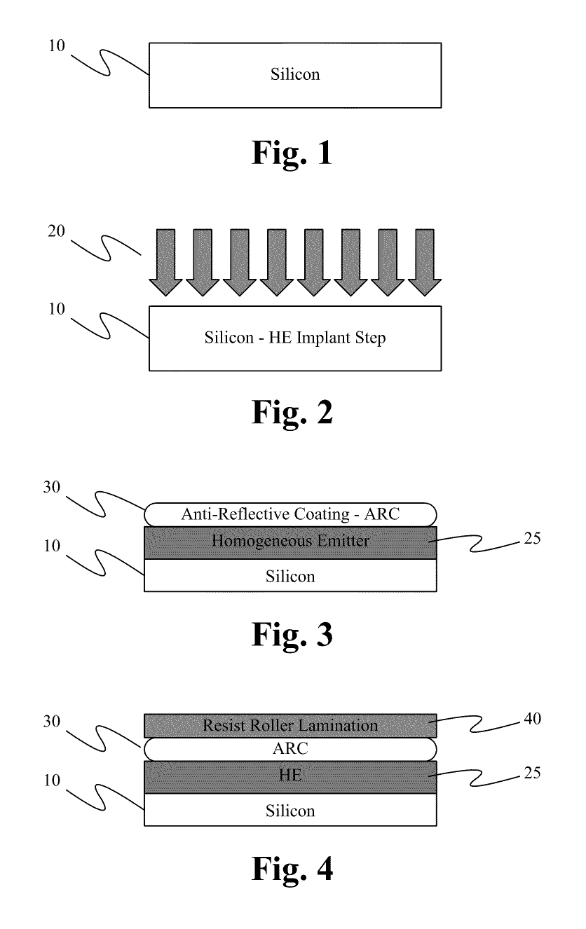

FIGS. 1-24 illustrate embodiments of a solar cell device, its characteristics, and its formation, with like elements being numbered alike. Various aspects of the disclosure may be described through the use of flowcharts. Often, a single instance of an aspect of the present disclosure may be shown. As is appreciated by those of ordinary skill in the art, however, the protocols, processes, and procedures described herein may be repeated continuously or as often as necessary to satisfy the needs described herein. Additionally, it is contemplated that method steps can be performed in a different order than the order illustrated in the figures, unless otherwise disclosed explicitly or implicitly.

The following is a description of solar cell fabrication methods that adopt many different approaches. These methods are viewed as cost effective, providing substantial gains in efficiencies.

FIGS. 1-14B illustrate different stages of one embodiment of fabricating a solar cell in accordance with the principles of the present invention. In some embodiments, the present invention's approach to cell fabrication starts after an initial saw damage and texturing etch, as shown in FIG. 1. The semiconducting substrate 10, at this stage, can be doped. In some embodiments, the substrate 10 is doped with p-type dopant (e.g., boron) to a low resistivity of approximately 0.5 Ohms/square to 1.5 Ohm/square, which translates to uniform doping of less than 1E16 cm⁻³ throughout the substrate 10.

As seen in FIG. 2, the substrate 10 is then counter-doped using an ion implantation technique to form a p-n junction. As seen in FIG. 3, this ion implantation forms a homogeneous emitter region 25. The level of doping for homogeneous emitter region 25 has to be low enough so as not to impede the conversion of light and the recombination of the minority carriers. Accordingly, in some embodiments, the level of doping is such that it results in the homogeneous emitter region 25 having a sheet resistance of approximately 100 Ohms/square or greater, with a surface dopant atomic concentration of approximately 1E19 cm⁻³ at this stage and the profile rolling off to the junction. In some embodiments, the level of doping is such that it results in the homogeneous emitter region 25 having a sheet resistance of between approximately 80 Ohms/square and approximately 160 Ohms/square. Preferably, the carrier diffusion length in the homogeneous emitter region 25 is similar to the junction depth so as to render this region as a transparent emitter. The control of surface concentration to less than approximately 1e19 cm⁻³ ensures that there is no pile-up of excess dopant on the near surface region, and thus eliminates the “dead layer” effect that precludes the use of energetic blue light for conversion. In a preferred embodiment, the p-n junction depth is at least 0.3 to 0.4 micron, thus minimizing the possibilities of metal shunting beyond the emitter region. A typical anti-reflective coating (ARC) is around 0.07 micron. Therefore, the total depth for the metal shunts is preferably in excess of 0.37 to 0.47 micron, which is more than adequate for the present firing thermal budgets.

This technique could also be used to improve the pre-doping of the starting material, through a uniform-like doping of the material, which is particularly important for low quality material that has both axial and lateral pre-doping non-uniformity. A typical ingot, as pulled, will have variation of dopant distribution axially from top to bottom of the ingot, as well as laterally. So once the ingot is cut into wafers, there may be variation of dopant from one side of the wafer to the other. As a result of the present invention's use of ion implantation, where a high level of dopant uniformity can be achieved and well controlled, a light dose can provide a more uniform back ground doping. Furthermore, with the recent drive to conserve as much of the pulled silicon as possible, sometimes the outer ends of the ingot are discarded or placed back into the melt, as resistivity deteriorates markedly. These sections can be retrieved, after wafering, and implanted to match the resistivity to the remainder of the wafers from the middle sections of the ingot. The consequence of such is that the wafers starting into the line will have a far higher consistency and thus will provide a more repeatable performance, thereby leading to a much tighter binning of the final product and thus leading to higher revenue.

As seen in FIG. 3, the wafer is next subjected to deposition of anti-reflective coating (ARC) film 30 that acts both for passivation of the surface and as an anti-reflective film to enhance the light path through the substrate. Additionally or alternatively, the ARC films can be deposited prior to the previous homogeneous emitter implantation, as the quality of the film may not be affected by the light doping levels.

As seen in FIG. 4, a resist layer 40 can be applied to the wafer using a simple roller system, thereby laminating a dual layered organic film, such as Dupont MM500 or Shell SU8 and other alternatives, on the surface. The adhesion of this film and the continuity is critical at this stage. Preferably, the lamination process is operated at a low temperature of approximately 50-100 degrees Celsius and through preheated physical rollers at a speed of 1 to 2 mm/min. At this rate and temperature, the substrate will not experience more than 50 degrees Celsius.

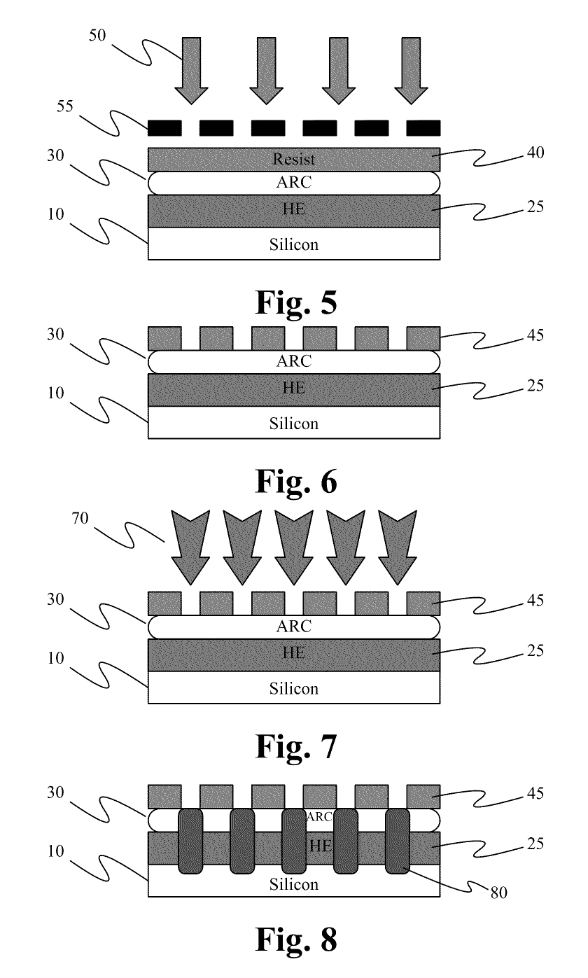

As seen in FIG. 5, a negative in-contact mask 55 is then placed on the resist film 40. The mask 55 can simulate the gridline pattern of the typical solar cell. It can also incorporate the bus bars. At present, the requirements for these grid lines is 100 to 150 micron wide with a spacing of 2 to 2.5 mm. It is contemplated that these requirements, in the near future, can be reduced to approximately 50 microns wide with a spacing of less than 1 mm in order to minimize the shadowing. Additionally, the metal gridline firing requirements at 810 degrees Celsius causes widening of the as-printed line by 20 to 30 micron, further aggravating the shadowing.

The in-contact masking 55 is placed in proximity of the wafer surface, and a basic and crude alignment is conducted with the edges of the wafer. Once in place, the wafer and the mask 55 are exposed to light 50 from a set of lamps that compliment the peak resist response of 350 to 380 nm. In order to achieve a grid line opening of 50 microns, a high resist step of 10 to 18 with about 28-60 mJ/cm2 is used.

As seen in FIG. 6, openings are formed in the resist layer 40, thereby creating an exposed resist layer 45. The exposed resist layer 45 can be developed in typical Sodium (Na₂CO₃, with less than 1.0 wt %) or Potassium carbonate (K₂CO₃, with less than 1.0 wt %). Preferably, buffered chemistries are not used here, as they impact the quality of the side wall and the resolution of the resist. The solution can be held at less than 35 degrees Celsius with a dwell time of 50 to 70 seconds. The wafer can then be subsequently irrigated and rinsed with direct fan nozzle and is blow-dried with hot air.

At this stage, the wafer is ready for the selective implantation step shown in FIG. 7. Here, the pattern of the resist 45 allows for selective positioning of the dopant 70 across the wafer. In the patent applications previously referenced, as well as in U.S. Provisional Application No. 61/219,379, entitled “PLASMA GRID IMPLANT SYSTEM FOR USE IN SOLAR CELL FABRICATIONS,” filed Jun. 23, 2009 and in U.S. Provisional Application No. 61/185,596, entitled “APPLICATION SPECIFIC IMPLANT SYSTEM FOR USE IN SOLAR CELL FABRICATIONS,” filed Jun. 10, 2009), which are both hereby incorporated by reference as if set forth herein, a series of application specific implants is described that maximizes the beam utilization through use of broad beam or beam shaping. This capability coupled with the gridline patterns of the resist 45 allows for well defined lines.

As seen in FIG. 8, the selective implantation results in the formation of selective emitter regions 80 underneath where the metal contact gridlines will eventually be placed. In some embodiments, the selective emitter regions 80 have a low resistivity (i.e., high conductivity) of around 10 to 30 Ohms/square with a surface concentration of approximately 1E20 cm⁻³ and a junction depth of 0.45 microns or greater. In some embodiments, the selective emitter regions 80 have a sheet resistance in the range of approximately 10 Ohms/square to approximately 40 Ohms/square. The surface concentration needs to be high in order to allow for better contact formation. However, the surface concentration is limited by the solid solubility of the silicon substrate 10, which is approximately 4E20 cm⁻³ for boron and phosphorus doping. The independent formation of junction depth, the cross-over of one type of doping with the opposite back ground type (typically 1E16 cm⁻³ or less) at a certain depth, is critical as to avoid metal shunting after the firing of contact.

At this stage, the wafer can bediverted into regular screen printing methods, whereby the resist 45 are removed and the grid lines are screen printed in the traditional manner. However, the alignments of the selective emitter implant versus the metal screen printed gridline becomes critical. There are multiple methods to ensure such alignment takes place. A crude method would be to align with the edges of the wafer both during the selective emitter implant and screen printing, such as by using the virtual center of the wafer for alignment. This alignment may be affected by the inconsistency in the wafer cutting, and it can be a coarse alignment method. The introduction of fiducial markings during the initial selective emitter implant will alleviate this issue, and can be achieved either through laser markings or relying on the impact of the implanted surface discolorations. Such markings can be visibly seen in relatively high dose, which is commensurate with the selective emitter implanted dose. This is a very distinct marking and if a vision system is set at the screen printing to pick up the patterns of the selective emitter implanted gridlines, then the alignment with the screen printing will be simplified.

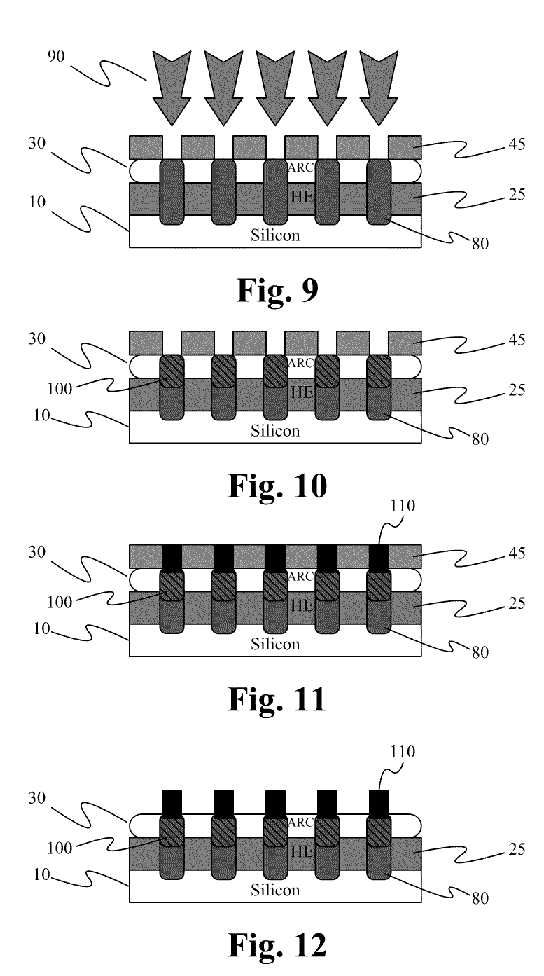

Alternatively, the resist 45 could remain on the wafers and the selective emitter implant can be followed by a “seed” or mesotaxy implant 90 for the formation of contact, as seen in FIG. 9. This seed implantation can be performed using a similar system to the selective emitter implant system described in the patent applications referenced above. Mesotaxy is the growth of a crystallographically matching phase underneath the very near surface of the host crystal. In this process, ions are implanted at the energy and dose into a material to create a very near surface layer of a second phase, and the temperature is controlled so that the crystal structure of the target is not destroyed. The crystal orientation of the layer can be engineered to match that of the target, even though the exact crystal structure and lattice constant may be very different. For example, after the implantation of nickel ions into a silicon wafer, a layer of nickel silicide can be formed in which the crystal orientation of the silicide matches that of the silicon. This growth method is different from an epitaxial growth method, where crystals are grown on the surface. Such silicide formation will allow for band gap engineering of the transition of the two unlike materials, such as metal to semiconductor. At present, such transition is achieved through high-temperature firing, where the metal deposited on the surface is diffused into the substrate to improve the contact. However, due to the presence of the selective emitter regions 80 and the metal silicide, this may not be necessary. It is contemplated that the roughing of the surface that may arise from high dose heavy ions (metals, etc.) can offer better adhesion properties for the subsequent metal contacts after a Mesotaxy implant. Such improvements in the band gap engineering and adhesion can improve the metal/ semiconductor interface resistivity and thus lead to enhanced performance of the solar cell.

As seen in FIG. 10, the mesotaxy implant can be carried through the silicon dioxide masking layer or anti-reflective layer (ARC) 30 to form a region 100 that stretches from where the metal contact will eventually be placed on the surface of the ARC 30, through the ARC 30 to the semiconductor (e.g., to the selective emitter region 80). Here, implant profile tailoring will help improve the metal semiconductor interface. Such tailoring is discussed in the patent applications referenced above. However, such an implant will invariably affect the anti-reflective property of the ARC layer 30. But, as this is a very small region and a majority of it is below the metal gridlines, it will not affect the performance of the solar cell. Formation of a very thin conductive layer allows for many different metal deposition methods, such as cost effective plating.

An alternative method would be to utilize metal-rich ink jet printing to form a very thin layer on top of the ARC layer 30. Subsequent to a firing step, a metal transition layer will be formed from the surface to the semiconductor. The use of the self-aligned mask will ensure that the deposited layer will have good alignment and vertical side walls. If the resist 45 is selected so as to withstand the subsequent firing temperature required, then there will be no deleterious spreading and widening of the contact layer, thereby minimizing shadowing and improving the power conversion efficiency of the solar cell.

At this stage, as seen in FIG. 11, a very thin conductive metal contact layer 110 is formed in the gridline openings of the gridline resist pattern. In some embodiments, the gridline resist pattern is used for an electrically activated deposition, like electro-plating or indeed electro-less plating. Electroplating can provide a very thick layer of most metals very quickly and cost effectively for solar cell fabrication. Such plating has been utilized in other industries very cost effectively. However, in the field of solar cell fabrication, it has required multiple and expensive steps to enable such technique to be utilized. The present invention's use of a self-aligned mask and a mesotaxial implant or jet printing will, for the first time, enable the use of such an inexpensive metal plating technique.

After the deposition of the metal contact layer, the resist layer 45 can be ashed or chemically stripped, as seen in FIG. 12. In some embodiments, a NaOH solution (less than 3 wt %) or a KOH solution (less than 3 wt %) can be used, with a spray of 2.4 bars of pressure at a dwell time of a few seconds at 55 degrees Celsius. After this step, the solar cell will have highly efficient light conversion efficiencies in between the gridlines, with a highly conductive emitter region 80 underneath the metal grid lines 110, and thus will provide efficiency gains in the order of 1 to 2 absolute percentage points.

At present, the back surface of the solar cell is a series of blanket metal deposition that has several issues associated with it. The first step is to deposit aluminum on the substrate that acts as a buffer between the subsequent high conductivity silver contact and that will also provide partial doping to improve the metal-silicon interface resistivity. Aluminum is not an effective dopant, but serves the purpose. The aluminum is also not a good metal for the subsequent soldering of the contact wires, and thus a thicker layer of printed silver is required. The thermal expansion mismatch of aluminum and silicon, however, poses a problem in buckling and deforming of the cell. This problem can be alleviated by introduction of a boron-doped BSF layer prior to silver deposition. In the present invention, such a BSF layer can be formed using the applications specific homogeneous implanter described in the patent applications previously referenced.

More critically, minimization of metal contact gridlines and the consequential shadowing is another way of improving cell power conversion efficiency. To this end, there are a number of methods that can be employed. One method is to minimize the width of the gridlines and thus the shadowing. However, this minimization is difficult with the present screen printing methods, as they are reaching their limits of width printing at 100 micron or less. The subsequent and necessary firing further broadens these grid lines to +/−10 to 15 microns, thus accentuating the problem. The use of the self-alignment methods describe above and their ability to provide patterns having a 50 micron or less opening addresses this problem effectively. The mesotaxy implant or ink jet printing seed layers followed by plating will eliminate the need for aluminum deposition and improve the cell fabrication costs at the same time.

In some embodiments, the present invention utilizes the selectivity capability of the ion implantation to provide regions of low resistivity BSF on the back surface of the wafer. Such implants can be formed into lines, large islands, or even donut-shaped. A selective implanter, such as the one discussed in the patent applications referenced above, can easily be modified for the same type of doping as the substrate (for example, a p-type doping such as boron) and provide shaped island regions.

Furthermore, there are many new techniques that will eliminate shadowing altogether by moving all of the contacts to the back of the solar cell, and thus allow the front surface non-impeded exposure. The present invention's use of implantation, both homogenous and selective capability, in combination with the self-aligned patterning discussed above will allow for the formation of interdigitated alternate doping regions on the back side of the solar cell, while avoiding problems associated with lithography, complex etching, and diffusion methods.

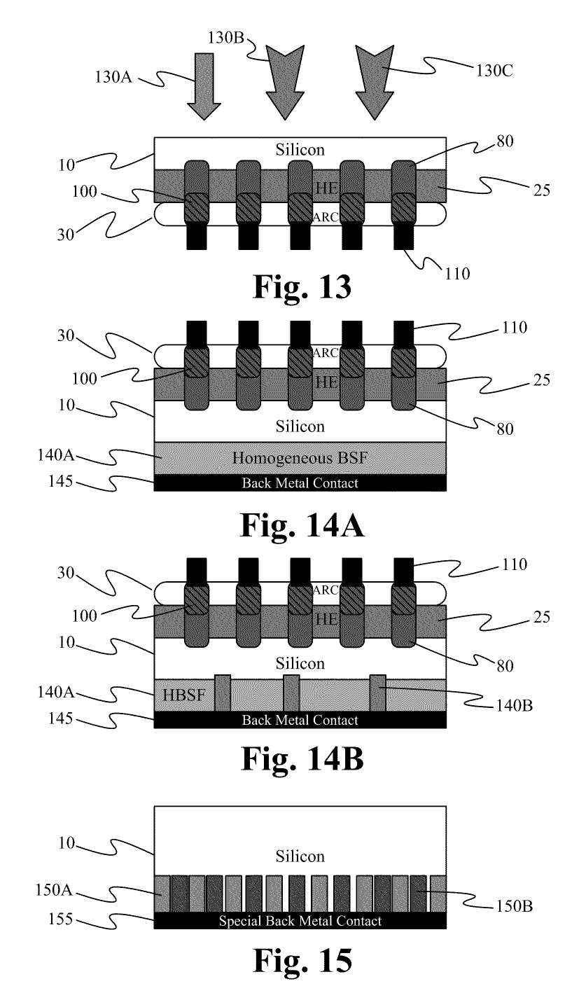

In FIG. 13, techniques such as described for the front surface emitter regions can be adopted to form a BSF or an interdigitated alternate dopant back doping cell (IBC). 130A shows the ability of the present invention to use the homogenous implanter to form a boron-doped BSF, which can replace the existing problematic aluminum-doped back surface. In a preferred embodiment, the implant provides a surface concentration of 1E19 cm⁻³ or less, with an independent junction formation capability of 0.5 microns or greater, and the resulting sheet resistivity of approximately 50 Ohms/square. Here, as the boron species is lighter than phosphorous, the same energy ranges can be adopted for the formation of these junctions. Preliminary work has shown that the applications specific implanter system previously referenced can very easily be used for the doping with any p-type doping. A typical outcome of such is shown in FIG. 14A, where a homogenous BSF 140 formed on the back side of the wafer, and is followed with a traditional back metal contact deposition 145. This combination, which is enabled by ion implantation, will yield conversion efficiency gains in the order 1 or more absolute percentage points.

130B shows the present invention's to use of a system similar to the selective emitter system described and referenced above, which can provide implanted islands of varying doping levels. These implants can be in the shape of gridlines or spots. Further more, the characteristic of a typical ion beam can be used to form a hollow-type implant around a possible contact point. FIG. 14B shows a combination of homogenous BSF (HBSF) 140A and selective BSF (SBSF) 140B. Such fabrication will enable the novel PERL cell (Martin Green et al.) very easily. The size of the islands are expected to be large enough, so as to minimize the need for tight beam shaping or self-aligned patterning methods and subsequent accurate alignments. Although smaller size implants are already possible, similar to the previously discussed selective emitter requirements.

The solar cell shown in the FIG. 14B will have all of the advantages of the front surface selective emitter higher conductivity, as well the homogeneous implanter emitter, without the dead layer effect. In addition, it will benefit from the boron BSF and highly-doped islands BSF. It is expected that this cell will provide extensive power efficiency gains over the traditional cells prevalent today. In the patent applications referenced above, the cost effectiveness of these methods is described, where it is shown that by replacing some of the present fabrication equipment and thus eliminating their costly operation, such cells can be fabricated cost effectively and at a high volume to meet the needs of the solar cell industry.

In FIG. 15, a novel interdigitated alternate dopant back doping cell (IBC) is shown, where by the selective capability of the previously discussed applications specific implanter is used in combination with the present self-alignment method, resulting in an elimination of the front surface shadowing. This front surface shadowing elimination is achieved by transferring all of the contacts to the back surface of the semiconducting wafer 10. In some embodiments, the emitter is formed similarly to the method described above, where the resist is patterned to accept one array of dopants 150A in any format required. Then, a second resist is patterned to allow the next and dis-similar dopant regions 150B to be formed. Such alternate doping on the rear side of the cell will not only minimize the front surface shadowing, but will also work effectively for poorer materials, where the minority carrier life time may be limited, as the distances between the emitter regions are much smaller than the dimension of the wafer itself.

In some embodiments, by careful selection of the masking layer (such as a sacrificial oxide) and/or the resist material and/or thickness, and by utilizing the depth penetration of the various species and their acceleration energy, the IBC can be fabricated with a one time self-alignment and patterning method. Again, this is enabled by the present inventions use of ion implantation, which can provide a depth penetration capability that is not available for the incumbent time- and temperature-driven diffusion methods. Such a one pass method allows one blanket implant to provide the selective and homogenous doping by careful selection of the masking layer thickness and other properties, as well as the mass and energy and angle of the implanted dopant or mixed species. In this method, the patterned resist can be the blocking agent to stop the unwanted species. Similarly, a sacrificial mask, such as SiO₂ or even the SiNₓ (ARC is typically Si₃N₄) can be utilized and patterned with resist to be the blocking agents for the unwanted species penetration. Such a sacrificial mask can be removed after the process, and will also have a side benefit of stopping any other unwanted contamination to affect the surface of the semiconductor.

In FIG. 15, a mesotaxial implant can form the required seed layer for the back metal contact layer 155. Similar to the previously discussed formation of silicide, this mesotaxial implant will help the band gap engineering between two unlike materials (metal and semiconductors), and also may enhance the adhesion of such. It is noted that the surface passivation layer for much thinner wafers will not pose problems on this back surface. Additionally, if no texturing is used for the rear side of the cell, then the methodology actually improves, as it does not have to cope with the larger surface that texturing offers.

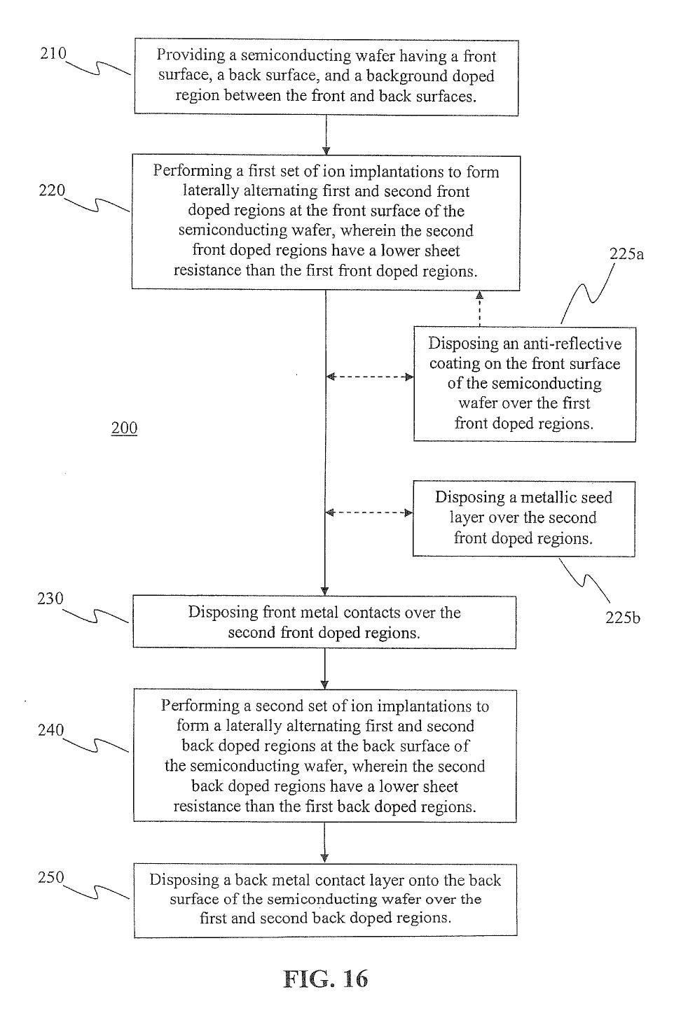

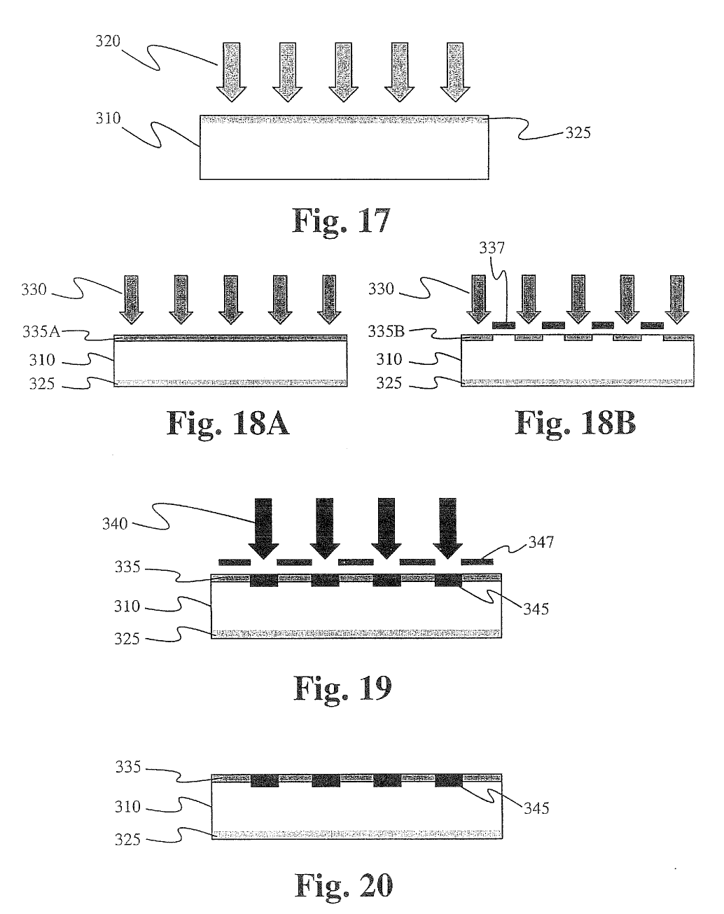

FIG. 16 illustrates one embodiment of a method 200 of fabricating a solar cell in accordance with the principles of the present invention. At step 210, a semiconducting wafer is provided having a front surface, a back surface, and a background doped region between the front surface and the back surface. In some embodiments, the semiconducting wafer is a silicon substrate. However, it is contemplated that other semiconducting materials can be used for the wafer.

At step 220, a first set of ion implantations of dopant into the semiconducting wafer is performed to form a front alternatingly-doped region extending from the front surface of the semiconducting wafer to a location between the front surface and the back surface. The front doped region comprises laterally alternating first front doped regions and second front doped regions. The second front doped regions (e.g., selective emitter regions) have a lower sheet resistance than the first front doped regions (e.g., homogeneous emitter regions). A p-n junction is formed between the first front doped regions and the background doped region.

In some embodiments, performing the first set of ion implantations comprises implanting the second front doped regions using a resist layer that comprises resist openings that are aligned with the locations on the semiconducting wafer where the second front doped regions are to be implanted. In some embodiments, the resist openings are formed using a contact mask placed in contact with the resist layer. The contact mask comprises mask openings that are aligned with the locations in the resist layer where the resist openings are to be formed.

At step 230, a plurality of front metal contacts is disposed on the semiconducting wafer. The front metal contacts are aligned over the second front doped regions, and are configured to conduct electrical charge from the second front doped regions.

At step 240, a second set of ion implantations of dopant into the semiconducting wafer is performed to form a back alternatingly-doped region extending from the back surface of the semiconducting wafer to a location between the back surface and the front surface. The back doped region comprises laterally alternating first back doped regions and second back doped regions. The second back doped regions have a lower sheet resistance than the first back doped regions.

In some embodiments, performing the second set of ion implantations comprises implanting the second back doped regions using a shadow mask that comprises mask openings that are aligned with the locations on the semiconducting wafer where the second back doped regions are to be implanted. The shadow mask is disposed a predetermined distance away from the back surface of the semiconducting wafer during a portion of the second set of ion implantations.

In some embodiments, the first front doped regions and the first back doped regions have a sheet resistance between approximately 80 Ohms/square and approximately 160 Ohms/square. In some embodiments, the second front doped regions and the second back doped regions have a sheet resistance between approximately 10 Ohms/square and approximately 40 Ohms/square. In some embodiments, the background doped region has a sheet resistance between approximately 0.5 Ohms/square and approximately 1.5 Ohms/square.

At step 250, a back metal contact layer is disposed onto the back surface of the semiconducting wafer. The back metal contact layer covers the first back doped regions and the second back doped regions, and is configured to conduct electrical charge from the second back doped regions.

It is contemplated that the method 200 can include other steps as well. For example, ast step 225a, an anti-reflective coating layer is disposed on the front surface of the semiconducting wafer over the first front doped regions. In some embodiments, this coating step is performed between ion implantations of the first set of ion implantations (e.g., between the implantation of the homogeneous emitter regions and the implantation of the selective emitter regions). As another example, at step 225b, a metallic seed layer is disposed over the second front doped regions. The front metal contacts of step 230 are then disposed over the metallic seed layer. In some embodiments, the metallic seed layer comprises mesotaxy implants. In some embodiments, the metallic seed layer comprises a silicide.

FIGS. 17-23 illustrate different stages of one embodiment of fabricating an inter-digitated back contact solar cell in accordance with the principles of the present invention. In some embodiments, a semiconducting wafers is etched and textured. For IBC cells, an n-type wafer is often used. However, it is contemplated that a p-type wafer can also be used.

In FIG. 17, the front of the semiconducting wafer 310 is lightly doped using ion implantation 320 to form a light dopant implant 325. This light dopant implant 325 helps with front side passivation and series resistance reduction. In some embodiments, the charge type of the light dopant implant 325 is the opposite of the charge type of the semiconducting wafer 310. For example, in some embodiments, if the semiconducting wafer 310 is an n-type wafer, then the light dopant implant 325 is a p-type implant.

Next, the wafer is then implanted on the rear side with the emitter doping. In some embodiments, for n-type wafers, the emitter would be a p-type implant, such as boron, aluminum, or gallium. This implant can be either a blanket implant or through a shadow mask to be patterned. FIG. 18A illustrates a blanket ion implantation 330 of the rear side of the wafer 310 to form emitter region 335A. FIG. 18B illustrates an ion implantation 330 of the rear side of the wafer 310 through a shadow mask 337 to form emitter regions 335B.

In FIG. 19, emitter region 335 is used to represent either one of emitter regions 335A and 335B. Base doping 340 is then performed on the rear side of the wafer 310 through a shadow mask 337 to form emitter regions 345. If the blanket doping of FIG. 18A was previously used, then this base doping 340 must be a high enough dose to counter dope the emitter doping 335A. In some embodiments, the charge type of emitter regions 345 is the same as the charge type of the wafer 310. For example, if an n-type wafer is being used, then the base doping 340 uses an n-type dopant, such as phosphorus, arsenic, or antimony.

In FIG. 20, the wafer is then exposed to either a rapid thermal anneal or a short furnace oxidation. This high-temperature step is used to active the dopants, anneal the implant damage, and to create a thin oxide layer which is highly passivating.

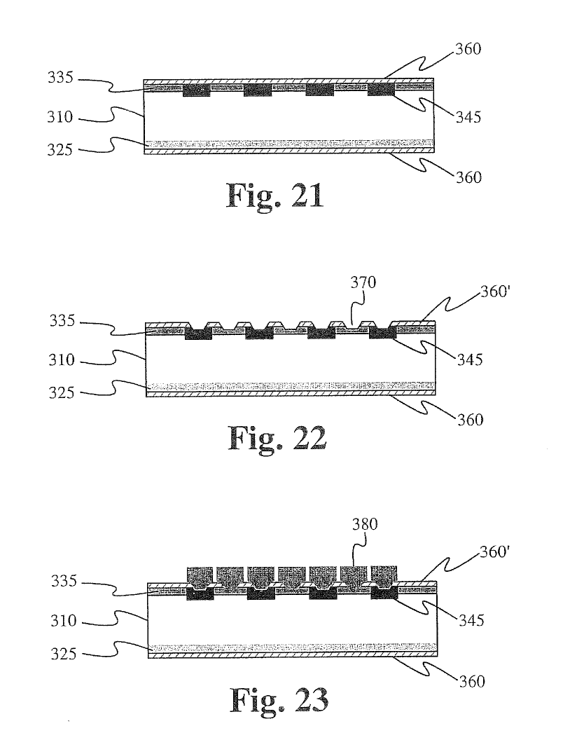

In FIG. 21, a silicon nitride film 360, or some other anti-reflection and passivating film, is deposited on the front and the back of the solar cell. In some embodiments, this film is deposited via a Plasma-Enhanced Chemical Vapor Deposition (PECVD) process.

In FIG. 22, a laser is used to ablate the anti-reflective coating layer 360 to form small separated openings 370 in the anti-reflective coating layer 360′ over the laterally alternating doped regions 335 and 345. In some embodiments, this ablation is performed using inexpensive fiber lasers and a beam steering mechanism.

In FIG. 23, metal contact fingers 380 of the interdigitated back contact are formed above the doped regions 335 and 345, contacting the wafer only through the separated openings 370. It is contemplated that different methods can be used to form such fingers 380. One method to form the fingers involves sputtering a seed metal, such as aluminum, through a shadow mask, and then thickening it using an electroplating process.

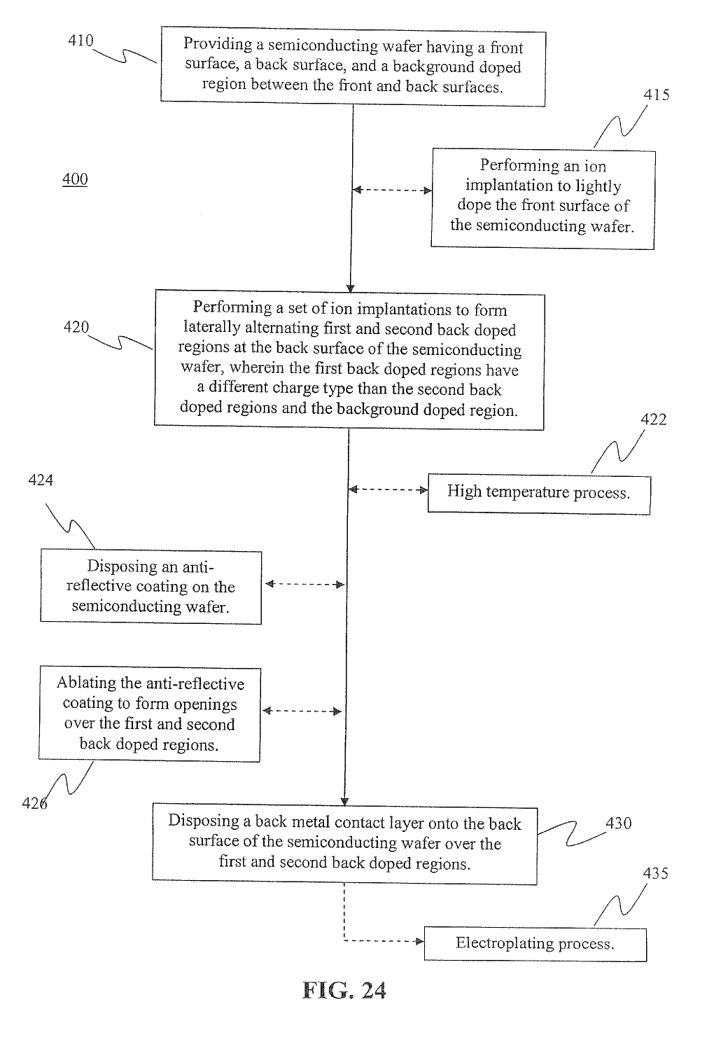

FIG. 24 illustrates one embodiment of a method 400 of fabricating an inter-digitated back contact solar cell in accordance with the principles of the present invention. At step 410, a semiconducting wafer is provided having a front surface, a back surface, and a background doped region between the front surface and the back surface. In some embodiments, the semiconducting wafer is a silicon substrate. However, it is contemplated that other semiconducting materials can be used for the wafer.

At step 420, a set of ion implantations of dopant into the semiconducting wafer are performed to form a back alternatingly-doped region extending from the back surface of the semiconducting wafer to a location between the back surface and the front surface. The back doped region comprises laterally alternating first back doped regions and second back doped regions. The first back doped regions comprise a different charge type than the second back doped regions and the background doped region.

In some embodiments, the step of performing a set of ion implantations comprises performing a blanket ion implantation of a first dopant into the semiconducting wafer, wherein the first dopant is implanted across the entire back surface of the semiconducting wafer, and performing a masked ion implantation of a second dopant into the semiconducting wafer using a shadow mask disposed a predetermined distance away from the back surface of the semiconducting wafer, wherein the shadow mask comprises mask openings that are aligned with the locations on the semiconducting wafer where the second back doped regions are to be implanted.

In some embodiments, the step of performing a set of ion implantations comprises performing a first masked ion implantation of a first dopant into the semiconducting wafer using a shadow mask disposed a predetermined distance away from the back surface of the semiconducting wafer, wherein the shadow mask comprises mask openings that are aligned with the locations on the semiconducting wafer where the first back doped regions are to be implanted, and performing a second masked ion implantation of a second dopant into the semiconducting wafer using a shadow mask disposed a predetermined distance away from the back surface of the semiconducting wafer, wherein the shadow mask comprises mask openings that are aligned with the locations on the semiconducting wafer where the second back doped regions are to be implanted.

In some embodiments, the background doped region is n-type doped, the first back doped regions are p-type doped, and the second back doped regions are n-type doped. In some embodiments, the first back doped regions are doped with a dopant chosen from the group consisting of: boron, aluminum, and gallium. In some embodiments, the second back doped regions are doped with a dopant chosen from the group consisting of: phosphorous, arsenic, and antimony.

At step 430, a back metal contact layer is disposed onto the back surface of the semiconducting wafer. The back metal contact layer is aligned over the first and second back doped regions, and is configured to conduct electrical charge from the first and second back doped regions.

In some embodiments, the method 400 also comprises a step 415 of performing an ion implantation of a dopant into the semiconducting wafer to form a lightly doped front region extending from the front surface of the semiconducting wafer to a location between the front surface and the back surface. In some embodiments, this lightly doped front region does not extend to or past the location of the back alternatingly-doped region. In some embodiments, this front doped region is p-type doped.

In some embodiments, the method 400 includes a step 422 where a high-temperature process is used on the wafer to active the dopants, anneal the implant damage, and to create a thin oxide layer, which is highly passivating the wafer is then exposed to either a rapid thermal anneal or a short furnace oxidation. In some embodiments, this high-temperature process involves exposing the wafer to either a rapid thermal anneal or a short furnace oxidation.

In some embodiments, the method 400 includes a step 424 where an anti-reflective coating layer is deposited over the front surface and the back surface of the semiconducting wafer. In some embodiments, the anti-reflective coating layer is deposited using a Plasma-Enhanced Chemical Vapor Deposition (PECVD) process. In some embodiments, the anti-reflective coating layer comprises silicon nitride.

In some embodiments, the method includes a step 426 where the anti-reflective coating layer is ablated to form separated openings in the anti-reflective coating layer over the first and second back doped regions. It is within these separated openings that the metal contacts are eventually deposited. In some embodiments, the method includes a step 435 where an electroplating process is performed after the metal contacts have been deposited within the separated openings.

An inter-digitated back contact cell can be inexpensively fabricated with the implantation of the present invention, which can be used to greatly reduce the cost and process steps currently used to create back contact cells, while maintaining the high solar cell efficiencies. Currently, the only commercial seller of back contact solar cells is Sunpower, which has an expensive and many-step process to make solar cells. The current commercial process used to process back contact solar cells involves at least twenty steps and has a cost of approximately $0.80/Wp. The process of the present invention requires fewer steps and dramatically reduces the cost to approximately $0.25/Wp.

The present invention has been described in terms of specific embodiments incorporating details to facilitate the understanding of principles of construction and operation of the invention. Such reference herein to specific embodiments and details thereof is not intended to limit the scope of the claims appended hereto. It will be readily apparent to one skilled in the art that other various modifications may be made in the embodiment chosen for illustration without departing from the spirit and scope of the invention as defined by the claims.

What is claimed is:

1. A solar cell comprising:
a semiconducting wafer having a front surface, a back surface, and a background doped region between the front surface and the back surface;
a front alternatingly-doped region extending from the front surface of the semiconducting wafer to a location between the front surface and the back surface, wherein the front doped region comprises laterally alternating first front doped regions and second front doped regions, the second front doped regions having a lower sheet resistance than the first front doped regions, and wherein a p-n junction is formed between the first front doped regions and the background doped region;
a plurality of front metal contacts aligned over the second front doped regions, wherein the front metal contacts are configured to conduct electrical charge from the second front doped regions;
a back alternatingly-doped region extending from the back surface of the semiconducting wafer to a location between the back surface and the front surface, wherein the back doped region comprises laterally alternating first back doped regions and second back doped regions, the second back doped regions having a lower sheet resistance than the first back doped regions; and
a back metal contact layer disposed on the back surface of the semiconducting wafer, wherein the back metal contact layer covers the first back doped regions and the second back doped regions and is configured to conduct electrical charge from the second back doped regions.

2. The solar cell of claim 1, wherein the semiconducting wafer is a silicon substrate.

3. The solar cell of claim 1, wherein the first front doped regions and the first back doped regions have a sheet resistance between approximately 80 Ohms/square and approximately 160 Ohms/square.

4. The solar cell of claim 1, wherein the second front doped regions and the second back doped regions have a sheet resistance between approximately 10 Ohms/square and approximately 40 Ohms/square.

5. The solar cell of claim 1, wherein:
the first front doped regions and the first back doped regions have a sheet resistance between approximately 80 Ohms/square and approximately 160 Ohms/square; and
the second front doped regions and the second back doped regions have a sheet resistance between approximately 10 Ohms/square and approximately 40 Ohms/square.

6. The solar cell of claim 5, wherein the background doped region has a sheet resistance between approximately 0.5 Ohms/square and approximately 1.5 Ohms/square.

7. The solar cell of claim 1, further comprising an anti-reflective coating layer disposed on the front surface of the semiconducting wafer over the first front doped regions.

8. The solar cell of claim 1, further comprising a metallic seed layer disposed over the second front doped regions and under the front metal contacts.

9. The solar cell of claim 8, wherein the metallic seed layer comprises mesotaxy implants.

10. The solar cell of claim 8, wherein the metallic seed layer comprises a silicide.

11. The solar cell of claim 1, wherein the second front doped regions are laterally spaced apart from one another a distance in the range of approximately 1 mm to approximately 3 mm.

12. The solar cell of claim 1, wherein:
the background doped region is p-type doped; and
the first front doped regions and the second front doped regions are n-type doped.

13. The solar cell of claim 12, wherein the second back doped regions are doped with the same charge-type dopant as the background doped region.

14. The solar cell of claim 13, wherein the first back doped regions are doped with the same charge-type dopant as the second back doped regions and the background doped region.

15. The solar cell of claim 13, wherein the second back doped regions and the background doped region are p-type doped.

16. The solar cell of claim 15, wherein the second back doped regions are doped with boron.

17. A method of fabricating a solar cell, the method comprising:
providing a semiconducting wafer having a front surface, a back surface, and a background doped region between the front surface and the back surface;
performing a first set of ion implantations of dopant into the semiconducting wafer to form a front alternatingly-doped region extending from the front surface of the semiconducting wafer to a location between the front surface and the back surface, wherein the front doped region comprises laterally alternating first front doped regions and second front doped regions, the second front doped regions having a lower sheet resistance than the first front doped regions, and wherein a p-n junction is formed between the first front doped regions and the background doped region;
disposing a plurality of front metal contacts on the semiconducting wafer, wherein the front metal contacts are aligned over the second front doped regions and are configured to conduct electrical charge from the second front doped regions;
performing a second set of ion implantations of dopant into the semiconducting wafer to form a back alternatingly-doped region extending from the back surface of the semiconducting wafer to a location between the back surface and the front surface, wherein the back doped region comprises laterally alternating first back doped regions and second back doped regions, the second back doped regions having a lower sheet resistance than the first back doped regions; and
disposing a back metal contact layer onto the back surface of the semiconducting wafer, wherein the back metal contact layer covers the first back doped regions and the second back doped regions and is configured to conduct electrical charge from the second back doped regions.

18. The method of claim 17, wherein performing the first set of ion implantations comprises implanting the second front doped regions using a resist layer that comprises resist openings that are aligned with the locations on the semiconducting wafer where the second front doped regions are to be implanted.

19. The method of claim 18, wherein the resist openings are formed using a contact mask placed in contact with the resist layer, the contact mask comprising mask openings that are aligned with the locations in the resist layer where the resist openings are to be formed.

20. The method of claim 17, wherein performing the second set of ion implantations comprises implanting the second back doped regions using a shadow mask that comprises mask openings that are aligned with the locations on the semiconducting wafer where the second back doped regions are to be implanted, and the shadow mask is disposed a predetermined distance away from the back surface of the semiconducting wafer during a portion of the second set of ion implantations.

21. The method of claim 17, wherein the semiconducting wafer is a silicon substrate.

22. The method of claim 17, wherein the first front doped regions and the first back doped regions have a sheet resistance between approximately 80 Ohms/square and approximately 160 Ohms/square.

23. The method of claim 17, wherein the second front doped regions and the second back doped regions have a sheet resistance between approximately 10 Ohms/square and approximately 40 Ohms/square.

24. The method of claim 17, wherein:
the first front doped regions and the first back doped regions have a sheet resistance between approximately 80 Ohms/square and approximately 160 Ohms/square; and
the second front doped regions and the second back doped regions have a sheet resistance between approximately 10 Ohms/square and approximately 40 Ohms/square.

25. The method of claim 24, wherein the background doped region has a sheet resistance between approximately 0.5 Ohms/square and approximately 1.5 Ohms/square.

26. The method of claim 17, further comprising the step of disposing an anti-reflective coating layer on the front surface of the semiconducting wafer over the first front doped regions.

27. The method of claim 17, further comprising the step of disposing a metallic seed layer over the second front doped regions, wherein the front metal contacts are disposed over the metallic seed layer.

28. The method of claim 27, wherein the metallic seed layer comprises mesotaxy implants.

29. The method of claim 27, wherein the metallic seed layer comprises a silicide.

30. The method of claim 17, wherein the second front doped regions are laterally spaced apart from one another a distance in the range of approximately 1 mm to approximately 3 mm.

31. The method of claim 17, wherein:
the background doped region is p-type doped; and
the first front doped regions and the second front doped regions are n-type doped.

32. The method of claim 17, wherein the second back doped regions are doped with the same charge-type dopant as the background doped region.

33. The method of claim 32, wherein the first back doped regions are doped with the same charge-type dopant as the second back doped regions and the background doped region.

34. The method of claim 32, wherein the second back doped regions and the background doped region are p-type doped.

35. The method of claim 34, wherein the second back doped regions are doped with boron.

36. A solar cell comprising:
a semiconducting wafer having a front surface, a back surface, and a background doped region between the front surface and the back surface;
a back alternatingly-doped region extending from the back surface of the semiconducting wafer to a location between the back surface and the front surface, wherein the back doped region comprises laterally alternating first back doped regions and second back doped regions, and wherein the first back doped regions comprise a different charge type than the second back doped regions and the background doped region; and
a back metal contact layer disposed on the back surface of the semiconducting wafer, wherein the back metal contact layer is aligned over the first and second back doped regions and is configured to conduct electrical charge from the first and second back doped regions.

37. The solar cell of claim 36, wherein the front surface of the semiconducting wafer is characterized by an absence of any metal contacts, thereby eliminating any front surface shadowing by metal contacts.

38. The solar cell of claim 36, wherein:
the background doped region is n-type doped;
the first back doped regions are p-type doped; and
the second back doped regions are n-type doped.

39. The solar cell of claim 38, wherein the first back doped regions are doped with a dopant chosen from the group consisting of: boron, aluminum, and gallium.

40. The solar cell of claim 38, wherein the second back doped regions are doped with a dopant chosen from the group consisting of: phosphorous, arsenic, and antimony.

41. The solar cell of claim 36, wherein the semiconducting wafer is a silicon substrate.

42. The solar cell of claim 36, further comprising a front doped region extending from the front surface of the semiconducting wafer to a location between the front surface and the back surface, wherein the front doped region does not extend to or past the location of the back alternatingly-doped region.

43. The solar cell of claim 42, wherein the front doped region is p-type doped.

44. The solar cell of claim 36, wherein the back metal contact layer comprises metal contact gridlines aligned over the first and second back doped regions.

45. The solar cell of claim 44, further comprising an anti-reflective coating layer disposed over the back surface of the semiconducting wafer and between the metal contact gridlines.

46. The solar cell of claim 45, wherein the anti-reflective coating layer comprises silicon nitride.

47. The solar cell of claim 36, further comprising an anti-reflective coating layer disposed over the front surface of the semiconducting wafer.

48. The solar cell of claim 47, wherein the anti-reflective coating layer comprises silicon nitride.

49. A method of fabricating a solar cell, the method comprising:
providing a semiconducting wafer having a front surface, a back surface, and a background doped region between the front surface and the back surface;
performing a set of ion implantations of dopant into the semiconducting wafer to form a back alternatingly-doped region extending from the back surface of the semiconducting wafer to a location between the back surface and the front surface, wherein the back doped region comprises laterally alternating first back doped regions and second back doped regions, and wherein the first back doped regions comprise a different charge type than the second back doped regions and the background doped region; and
disposing a back metal contact layer onto the back surface of the semiconducting wafer, wherein the back metal contact layer is aligned over the first and second back doped regions and is configured to conduct electrical charge from the first and second back doped regions.

50. The method of claim 49, wherein the step of performing a set of ion implantations of dopant into the semiconducting wafer to form a back alternatingly-doped region comprises:
performing a blanket ion implantation of a first dopant into the semiconducting wafer, wherein the first dopant is implanted across the entire back surface of the semiconducting wafer; and
performing a masked ion implantation of a second dopant into the semiconducting wafer using a shadow mask disposed a predetermined distance away from the back surface of the semiconducting wafer, wherein the shadow mask comprises mask openings that are aligned with the locations on the semiconducting wafer where the second back doped regions are to be implanted.

51. The method of claim 49, wherein the step of performing a set of ion implantations of dopant into the semiconducting wafer to form a back alternatingly-doped region comprises:
performing a first masked ion implantation of a first dopant into the semiconducting wafer using a shadow mask disposed a predetermined distance away from the back surface of the semiconducting wafer, wherein the shadow mask comprises mask openings that are aligned with the locations on the semiconducting wafer where the first back doped regions are to be implanted; and
performing a second masked ion implantation of a second dopant into the semiconducting wafer using a shadow mask disposed a predetermined distance away from the back surface of the semiconducting wafer, wherein the shadow mask comprises mask openings that are aligned with the locations on the semiconducting wafer where the second back doped regions are to be implanted.

52. The method of claim 49, wherein:
the background doped region is n-type doped;
the first back doped regions are p-type doped; and
the second back doped regions are n-type doped.

53. The method of claim 52, wherein the first back doped regions are doped with a dopant chosen from the group consisting of: boron, aluminum, and gallium.

54. The method of claim 52, wherein the second back doped regions are doped with a dopant chosen from the group consisting of: phosphorous, arsenic, and antimony.

55. The method of claim 49, wherein the semiconducting wafer is a silicon substrate.

56. The method of claim 49, further comprising the step of performing an ion implantation of a dopant into the semiconducting wafer to form a front doped region extending from the front surface of the semiconducting wafer to a location between the front surface and the back surface, wherein the front doped region does not extend to or past the location of the back alternatingly-doped region.

57. The method of claim 56, wherein the front doped region is p-type doped.

58. The method of claim 49, further comprising the step of depositing an anti-reflective coating layer over the front surface and the back surface of the semiconducting wafer.

59. The method of claim 58, wherein the anti-reflective coating layer is deposited using a Plasma-Enhanced Chemical Vapor Deposition (PECVD) process.

60. The method of claim 58, wherein the anti-reflective coating layer comprises silicon nitride.

61. The method of claim 58, wherein the step of disposing the back metal contact layer onto the back surface of the semiconducting wafer comprises:
ablating the anti-reflective coating layer to form separated openings in the anti-reflective coating layer over the first and second back doped regions; and
depositing metal contacts within the separated openings.

62. The method of claim 61, wherein the step of disposing the back metal contact layer onto the back surface of the semiconducting wafer further comprises performing an electroplating process after the metal contacts have been deposited within the separated openings.
